(19) United States
(12) Patent Application Publication
(10) Pub. No.: US 2026/0040823 A1
(43) Pub. Date: Feb. 5, 2026

(54) THERMOELECTRIC MODULE

(71) Applicant: KELK Ltd., Hiratsuka-shi (JP)

(72) Inventor: Satoshi Shirahata, Hiratsuka-shi (JP)

(73) Assignee: KELK Ltd., HIratsuka-Shi (JP)

(21) Appl. No.: 18/996,723

(22) PCT Filed: Sep. 4, 2023
(86) PCT No.: PCT/JP2023/032252

§ 371 Date: Jan. 17, 2025

(30) Foreign Application Priority Data
Sep. 9, 2022 (JP) 2022-143642

(51) Int. Cl. H10N 10/82; H10N 19/00

(52) U.S. Cl. CPC H10N 10/82; H10N 19/00

(57) ABSTRACT

A thermoelectric module is a thermoelectric module that performs temperature control on a temperature control target object, the thermoelectric module including: a plurality of thermoelectric elements that are provided between the temperature control target object and a substrate that is disposed to face the temperature control target object in a first direction; and a plurality of electrodes that are provided on each of a substrate side and a temperature control target object side of the thermoelectric element and configured to electrically connect the thermoelectric elements adjacent to each other in a second direction intersecting the first direction, in which the electrode includes two electrode base portions that are spaced apart from each other in the second direction, and each of which is connected to a corresponding thermoelectric element, and a connecting portion connecting the two electrode base portions.

### TECHNICAL FIELD

The present invention relates to a thermoelectric module.

Priority is claimed on Japanese Patent Application No. 2022-143642, filed Sep. 9, 2022, the content of which is incorporated herein by reference.

### BACKGROUND ART

In a thermoelectric module (Peltier module), electrodes are connected to end surfaces of a plurality of thermoelectric elements disposed on a substrate, and the thermoelectric elements adjacent to each other are electrically connected to each other by the electrodes. In a case where an electric current is passed through the thermoelectric module, an endothermic phenomenon occurs on one surface of the thermoelectric module to cool the electrode, and a heat dissipation phenomenon occurs on the other surface of the thermoelectric module to heat the electrode. By the endothermic phenomenon and the heat dissipation phenomenon, it is possible to perform temperature control on a temperature control target object mounted on the thermoelectric module.

However, in a case where the temperature is controlled by the thermoelectric module, a temperature difference occurs between the electrode on a first side and the electrode on a second side of the thermoelectric module. In this way, for example, the electrode on the first side is made to be in a state of thermal expansion or contraction with the electrode on the second side as a reference. On the other hand, since the electrode on the second side is fixed to the substrate, a load due to thermal stress is generated in a connection portion between the electrode on the first side and the thermoelectric element. By repeating the temperature control, thermal stress is repeatedly applied to the connection portion, and thus there is a concern that the connection portion may be broken at last.

As a countermeasure, for example, in Patent Document 1, an electrode is provided with a meandering portion. Since the meandering portion absorbs the expansion and contraction of the electrode during temperature control, the thermal stress acting on the connection portion between the electrode and the thermoelectric element is relaxed.

### CITATION LIST

### Patent Document

Patent Document 1: Japanese Unexamined Patent Application, First Publication No. H11-68175

### SUMMARY OF INVENTION

### Technical Problem

However, in Patent Document 1, the width of the electrode is increased due to the meandering portion, and the thermoelectric elements cannot be densely disposed, and thus there is a case where the output of the thermoelectric module is reduced.

The present invention has been made in order to solve the above-described problems, and an object of the present invention is to provide a thermoelectric module in which it is possible to avoid a reduction in output while relaxing thermal stress acting on an electrode.

### Solution to Problem

In order to solve the above-described problems, according to an aspect of the present invention, there is provided is a thermoelectric module that performs temperature control on a temperature control target object, the thermoelectric module including: a plurality of thermoelectric elements that are provided between the temperature control target object and a substrate that is disposed to face the temperature control target object in a first direction; and a plurality of electrodes that are provided on each of a substrate side and a temperature control target object side of the thermoelectric element and configured to electrically connect the thermoelectric elements adjacent to each other in a second direction intersecting the first direction, in which the electrode includes two electrode base portions that are spaced apart from each other in the second direction, and each of which is connected to a corresponding thermoelectric element, and a connecting portion connecting the two electrode base portions, and the connecting portion is provided with a hole portion penetrating in the first direction, a constriction portion that is provided on each of both sides in the second direction with the hole portion interposed therebetween and that is recessed inward in a third direction intersecting the first direction and the second direction, and a displacement absorbing portion formed along an outer shape of the connecting portion and an outer shape of the hole portion.

### Advantageous Effects of Invention

According to the present invention, it is possible to avoid a reduction in the output of the thermoelectric module while relaxing the thermal stress acting on the electrode.

### BRIEF DESCRIPTION OF DRAWINGS

FIG. 1 A side view of a thermoelectric unit according to a first embodiment of the present invention.

FIG. 2 A plan view showing disposition of a second electrode according to the first embodiment of the present invention.

FIG. 3 A plan view of the second electrode according to the first embodiment of the present invention.

FIG. 4 A plan view of a second electrode according to a modification example of the first embodiment of the present invention.

FIG. 5 A plan view of a second electrode according to a second embodiment of the present invention.

FIG. 6 A plan view of a second electrode according to a third embodiment of the present invention.

FIG. 7 A plan view of a second electrode according to a fourth embodiment of the present invention.

### DESCRIPTION OF EMBODIMENTS

### First Embodiment

### (Configuration of Thermoelectric Unit)

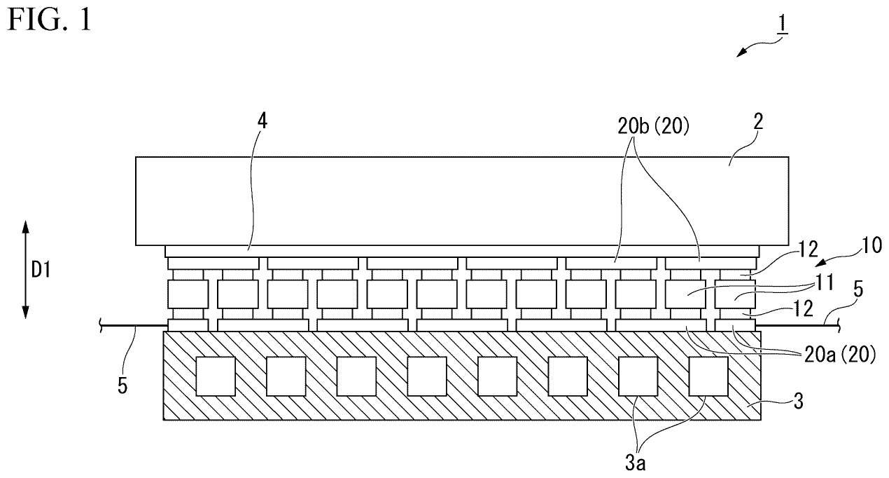

Hereinafter, a thermoelectric unit 1 that includes a thermoelectric module 10 according to a first embodiment of the present invention will be described with reference to FIGS. 1 to 3. The thermoelectric unit 1 shown in FIG. 1 includes a temperature control target object 2, a substrate 3, the thermoelectric module 10, a heat transfer member 4, and a lead wire 5.

### (Temperature Control Target Object)

The temperature control target object 2 includes a wide range of objects that change in temperature. As the temperature control target object 2, for example, a wafer stage of a semiconductor manufacturing apparatus, or the like can be given,

### (Substrate)

The substrate 3 is disposed to face the temperature control target object 2.

Hereinafter, the facing direction between the temperature control target object 2 and the substrate 3 will be referred to as a “first direction D1”.

The substrate 3 extends in a plane direction substantially perpendicularly intersecting the first direction D1. The substrate 3 is a heat radiation plate that radiates the heat from the thermoelectric module 10. A plurality of conduit lines 3a are provided in the substrate 3 over the entire substrate 3. Cooling water flows through the conduit line 3a. The cooling water absorbs the heat from the thermoelectric module 10.

### (Thermoelectric Module)

The thermoelectric module 10 performs temperature control on the temperature control target object 2. A detailed structure of the thermoelectric module 10 will be described later.

### (Heat Transfer Member)

The heat transfer member 4 is provided between the thermoelectric module 10 and the temperature control target object 2. The heat transfer member 4 thermally connects the thermoelectric module 10 and the temperature control target object 2. As the heat transfer member 4, for example, grease or the like can be given.

### (Lead Wire)

The lead wire 5 electrically connects the thermoelectric module 10 and an external power supply (not shown) to each other to energize the thermoelectric module 10. At least one pair of lead wires 5 are provided in the thermoelectric module 10.

### (Configuration of Thermoelectric Module)

Hereinafter, the configuration of the thermoelectric module 10 will be described. The thermoelectric module 10 includes a thermoelectric element 11 and an electrode 20.

### (Thermoelectric Element)

A plurality of thermoelectric elements 11 are provided between the substrate 3 and the temperature control target object 2.

### (Connection Portion)

Connection portions 12 are provided on both end surfaces in the first direction D1 of the thermoelectric element 11.

The connection portion 12 electrically and thermally connects the thermoelectric element 11 and the electrode 20 to each other.

### (Electrode)

The electrode 20 is provided on each of the substrate 3 side and the temperature control target object 2 side of the thermoelectric element 11. The electrode 20 electrically connects two adjacent thermoelectric elements 11 to each other.

Hereinafter, among the plurality of electrodes 20, the electrode 20 on the substrate 3 side in the first direction D1 will be referred to as a “first electrode 20a”, and the electrode 20 on the temperature control target object 2 side in the first direction D1 will be referred to as a “second electrode 20b”.

### (First Electrode)

A plurality of first electrodes 20a are provided on the substrate 3. The plurality of first electrodes 20a are thermally connected to the substrate 3. Each of the first electrodes 20a electrically connects the adjacent thermoelectric elements 11 to each other.

### (Second Electrode)

A plurality of second electrodes 20b are provided on a side opposite to the first electrode 20a with the thermoelectric element 11 interposed therebetween in the first direction D1. The plurality of second electrodes 20b are thermally connected to the temperature control target object 2 via the heat transfer member 4. Each of the second electrodes 20b electrically connects the thermoelectric elements 11 which are adjacent to each other and are connected to the first electrodes 20a different from each other.

The thermoelectric elements 11 are electrically connected by the plurality of first electrodes 20a and second electrodes 20b. The lead wire 5 is electrically connected to each of the first electrodes 20a located at both end portions of a unit that includes the thermoelectric element 11, the first electrode 20a, and the second electrode 20b which are electrically connected.

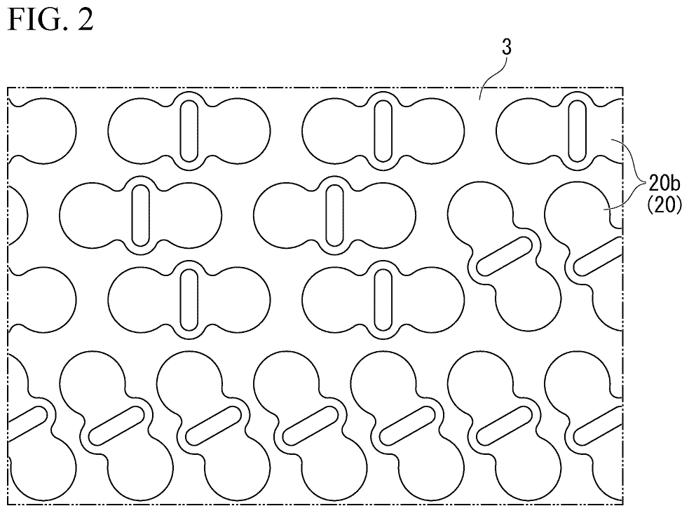

In addition, as shown in FIG. 2, the plurality of second electrodes 20b are densely disposed along the surface of the substrate 3.

Hereinafter, with respect to one second electrode 20b among the plurality of second electrodes 20b, in a plane direction substantially perpendicularly intersecting the “first direction D1”, the facing direction between two thermoelectric elements 11 that are connected by the second electrode 20b will be referred to as a “second direction D2”, and in the plane direction substantially perpendicularly intersecting the “first direction D1”, the direction substantially perpendicularly intersecting the “first direction D1” and the “second direction D2” will be referred to as a “third direction D3”.

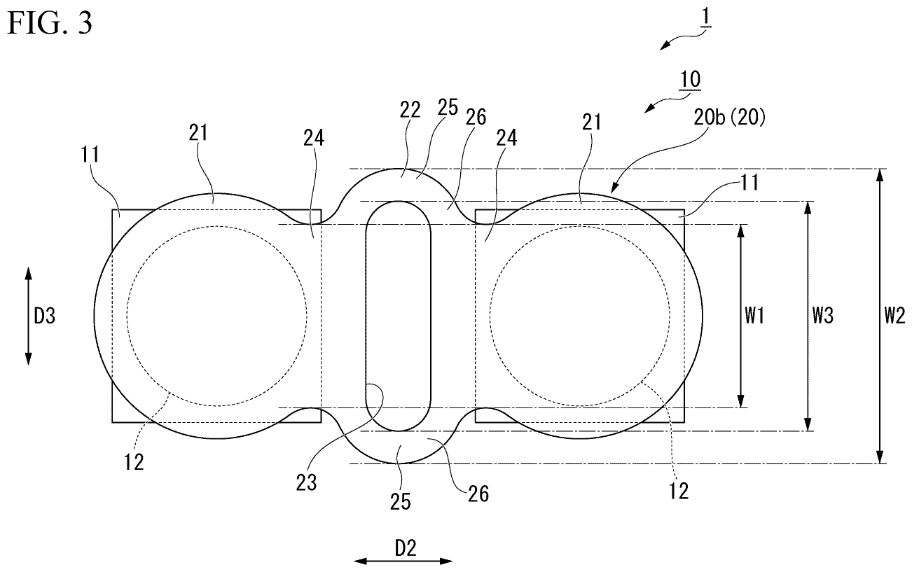

As shown in FIG. 3, the second electrode 20b is formed in a shape symmetrical in the second direction D2 and the third direction D3 when viewed in the first direction D1. Furthermore, the outer edge of the second electrode 20b is formed in a smooth curved shape. The second electrode 20b has an electrode base portion 21 and a connecting portion 22.

### (Electrode Base Portion)

A pair of electrode base portions 21 are provided to be spaced apart from each other in the second direction D2. The electrode base portion 21 is connected to a corresponding thermoelectric element 11. The outer edge of the electrode base portion 21 is formed in an arc shape when viewed in the first direction D1.

### (Connecting Portion)

The connecting portion 22 connects the two electrode base portions 21. The connecting portion 22 is formed integrally with the electrode base portion 21. The outer edge of the connecting portion 22 is formed to be smoothly curved when viewed in the first direction D1, and is smoothly connected to the outer edge of the electrode base portion 21. The connecting portion 22 is provided with a hole portion 23, a constriction portion 24, a protruding portion 25, and a displacement absorbing portion 26.

### (Hole Portion)

The hole portion 23 penetrates a center portion of the connecting portion 22 in the first direction D1. The hole portion 23 is formed by, for example, punching.

### (Constriction Portion)

The constriction portions 24 are provided on both sides in the second direction D2 with the hole portion 23 interposed therebetween.

The constriction portion 24 is formed to be recessed inward in the third direction D3. The outer edge of the constriction portion 24 is formed in a curved shape to be recessed inward in the third direction D3 when viewed in the first direction D1, and is smoothly connected to the outer edge of the electrode base portion 21.

The constriction portion 24 is formed by, for example, cutting.

### (Protruding Portion)

The protruding portion 25 is provided on the outer side of the hole portion 23 in the third direction D3. The protruding portion 25 protrudes in the third direction D3. The outer edge of the protruding portion 25 is formed in a curved shape to protrude outward in the third direction D3 when viewed in the first direction D1, and is smoothly connected to the outer edge of the constriction portion 24.

The hole portion 23 of the present embodiment is enlarged in the third direction D3 in accordance with the protruding portion 25.

### (Displacement Absorbing Portion)

The displacement absorbing portion 26 is formed along the outer shape of the connecting portion 22 and the outer shape of the hole portion 23. More specifically, the displacement absorbing portion 26 is formed along the outer shapes of the hole portion 23, the constriction portion 24, and the protruding portion 25. The displacement absorbing portion 26 extends along the second direction D2.

### (Dimensions of Second Electrode)

Subsequently, the dimensions of the second electrode 20b will be described.

Hereinafter, the width in the third direction D3 of the constriction portion 24 of the second electrode 20b will be referred to as a “first width W1”. Further, the width in the third direction D3 of the protruding portion 25 of the second electrode 20b will be referred to as a “second width W2”, and the width in the third direction D3 of the hole portion 23 will be referred to as a “third width W3”.

In this case, the second electrode 20b is formed such that the relationship shown in the following expression is satisfied.

W1<W3<W2

### (Operation of Thermoelectric Module)

Subsequently, the operation of the thermoelectric module 10 will be described.

In the following, a case where the temperature of the temperature control target object 2 that generates heat is maintained constant will be described as an example.

First, the unit that includes the plurality of thermoelectric elements 11, the first electrode 20a, and the second electrode 20b, which is connected to an external power supply (not shown) by the lead wire 5, is energized. Then, the second electrode 20b absorbs the heat from the temperature control target object 2. Then, the first electrode 20a radiates the heat of the temperature control target object 2 toward the substrate 3. The heat radiated from the first electrode 20a is transferred to the cooling water flowing through the conduit line 3a in the substrate 3, thereby being radiated to the outside.

In this case, a temperature difference occurs between both end surfaces in the first direction D1 of the thermoelectric element 11. The first electrode 20a is fixed to the substrate 3, whereas the second electrode 20b is not fixed to the temperature control target object 2. Therefore, the second electrode 20b is easily affected by thermal stress due to the temperature difference in the thermoelectric element 11, compared to the first electrode 20a. The second electrode 20b is thermally expanded and thermally contracted in the second direction D2 due to thermal stress. Since there is a concern that a joint portion (in the shown example, the connection portion 12 on the temperature control target object 2 side) between the second electrode 20b and the thermoelectric element 11 may be damaged due to the thermal expansion and thermal contraction of the second electrode 20b, it is necessary to relax the thermal stress acting on the second electrode 20b.

The second electrode 20b of the present embodiment is provided with the displacement absorbing portion 26. In a case where the thermal stress acts on the second electrode 20b, the displacement absorbing portion 26 stretches and contracts in the second direction D2, so that the thermal stress is relaxed.

### Effect

The thermoelectric module 10 according to the first embodiment described above can exhibit the following effects.

In the present embodiment, the thermoelectric module 10 includes the plurality of thermoelectric elements 11 and the plurality of electrodes 20. The plurality of thermoelectric elements 11 are provided between the temperature control target object 2 and the substrate 3 disposed to face the temperature control target object 2 in the first direction D1. The plurality of electrodes 20 are provided on each of the substrate 3 side and the temperature control target object 2 side of the thermoelectric element 11, and electrically connect the thermoelectric elements 11 adjacent to each other in the second direction D2 intersecting the first direction D1. Further, the electrode 20 has the two electrode base portions 21 and the connecting portion 22. The two electrode base portions 21 are spaced apart from each other in the second direction D2, and each of the electrode base portions 21 is connected to a corresponding thermoelectric element 11. The connecting portion 22 connects the two electrode base portions 21. Further, the connecting portion 22 is provided with the hole portion 23, the constriction portion 24, and the displacement absorbing portion 26. The hole portion 23 penetrates in the first direction D1.

The constriction portions 24 are provided on both sides in the second direction D2 with the hole portion 23 interposed therebetween, and are recessed inward in the third direction D3 intersecting the first direction D1 and the second direction D2. The displacement absorbing portion 26 is formed along the outer shape of the connecting portion 22 and the outer shape of the hole portion 23.

According to the above-described configuration, the displacement absorbing portion 26 is formed in a wavy shape that extends in the second direction D2 while being displaced in the third direction D3. Therefore, in a case where the thermal stress in the second direction D2 acts on the second electrode 20b, the displacement absorbing portion 26 stretches and contracts in the second direction D2, so that the thermal stress can be relaxed. Further, the displacement absorbing portions 26 are provided on both sides in the third direction D3 with the hole portion 23 interposed therebetween. In this way, thermal stress evenly acts on the two displacement absorbing portions 26, and a force in a twisting direction can be prevented from being generated at the joint portion between the second electrode 20b and the thermoelectric element 11.

In addition, since the wavy shape of the displacement absorbing portion 26 is formed by the hole portion 23 and the constriction portion 24, it is possible to prevent the displacement absorbing portion 26 from greatly protruding outward in the third direction D3. In this way, the second electrode 20b can be densely disposed along the substrate 3. Therefore, since the thermoelectric elements 11 can be densely disposed on the substrate 3, the output of the thermoelectric module 10 can be sufficiently secured.

In this manner, according to the present embodiment, it is possible to avoid a reduction in the output of the thermoelectric module 10 while relaxing the thermal stress acting on the second electrode 20b.

In the present embodiment, the second electrode 20b has the protruding portion 25. The protruding portion 25 is provided on the outer side in the third direction D3 of the hole portion 23 and protrudes in the third direction D3. The hole portion 23 is enlarged in the third direction D3 in accordance with the protruding portion 25.

In this way, the displacement absorbing portion 26 is lengthened, and the amount of stretch and contraction of the displacement absorbing portion 26 in the second direction D2 can be secured more. Therefore, the thermoelectric module 10 can further satisfactorily relax the thermal stress by the stretch and contraction of the displacement absorbing portion 26.

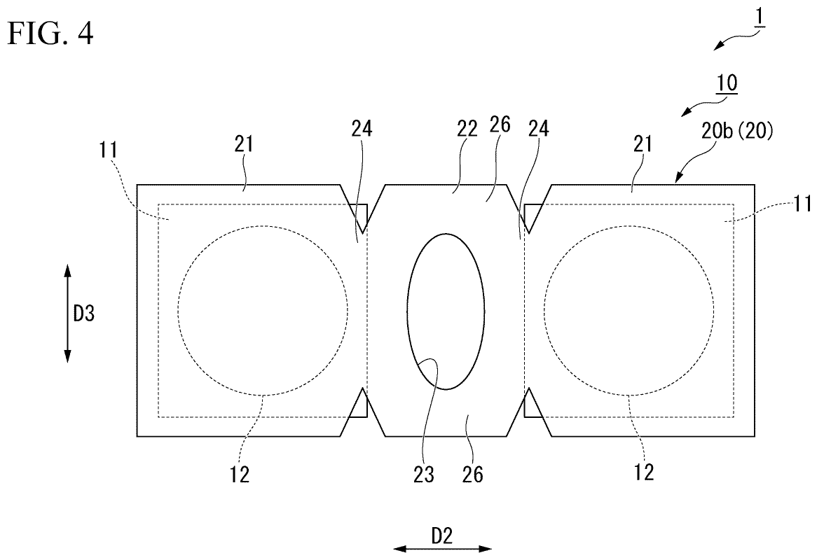

In the first embodiment, a case where the second electrode 20b has the protruding portion 25 has been described. However, as shown in FIG. 4, the second electrode 20b does not necessarily need to have the protruding portion 25.

In addition, the outer edge of the second electrode 20b does not necessarily need to be curved, and the outer edge of the second electrode 20b may be formed in a linear shape, as shown in FIG. 4.

### Second Embodiment

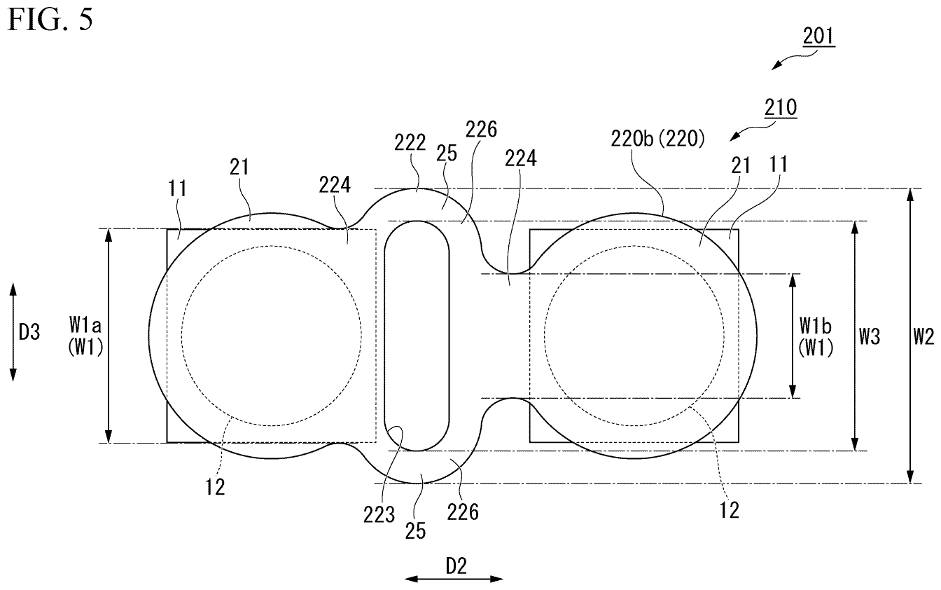

Next, a thermoelectric unit 201 that includes a thermoelectric module 210 according to a second embodiment of the present invention will be described with reference to FIG. 5. In the second embodiment, the same components as those in the embodiment described above are denoted by the same reference numerals, and a detailed description thereof will be omitted.

The thermoelectric unit 201 of the present embodiment includes the temperature control target object 2, the substrate 3, the thermoelectric module 210, the heat transfer member 4, and the lead wire 5.

The thermoelectric module 210 includes the plurality of thermoelectric elements 11 and a plurality of electrodes 220. The plurality of electrodes 220 include the plurality of first electrodes 20a and a plurality of second electrodes 220b.

As shown in FIG. 5, the second electrode 220b is formed asymmetrically in the second direction D2.

The second electrode 220b has the electrode base portion 21 and a connecting portion 222.

The connecting portion 222 has a hole portion 223, a constriction portion 224, the protruding portion 25, and a displacement absorbing portion 226.

The hole portion 223 is provided close to the thermoelectric element 11 on a first side in the second direction D2 out of the two thermoelectric elements 11 which are electrically connected to each other.

The constriction portion 224 on a second side in the second direction D2 out of the constriction portions 224 on both sides in the second direction D2 with the hole portion 223 interposed therebetween is recessed further inward in the third direction D3 than the constriction portion 224 on the first side in the second direction D2.

Therefore, in the first width W1 of the constriction portion 224, a first width W1b of the constriction portion 224 on the second side in the second direction D2 is smaller than a first width W1a of the constriction portion 224 on the first side in the second direction D2.

### Effect

The thermoelectric module 210 according to the second embodiment described above can exhibit the following effects.

In the present embodiment, the hole portion 223 is provided close to the thermoelectric element 11 on the first side in the second direction D2 out of the two thermoelectric elements 11 which are electrically connected to each other. The constriction portion 224 on the second side in the second direction D2 is recessed further inward in the third direction D3 than the constriction portion 224 on the first side in the second direction D2.

In this way, the displacement absorbing portion 226 is lengthened, and the amount of stretch and contraction in the second direction D2 of the displacement absorbing portion 226 can be secured more. Therefore, the thermoelectric module 210 can further satisfactorily relax the thermal stress by the stretch and contraction of the displacement absorbing portion 226.

Furthermore, since the width in the second direction D2 of the connecting portion 222 corresponding to the constriction portion 224 on the side recessed inward can be secured, the processing of forming the constriction portion 224 is facilitated.

### Third Embodiment

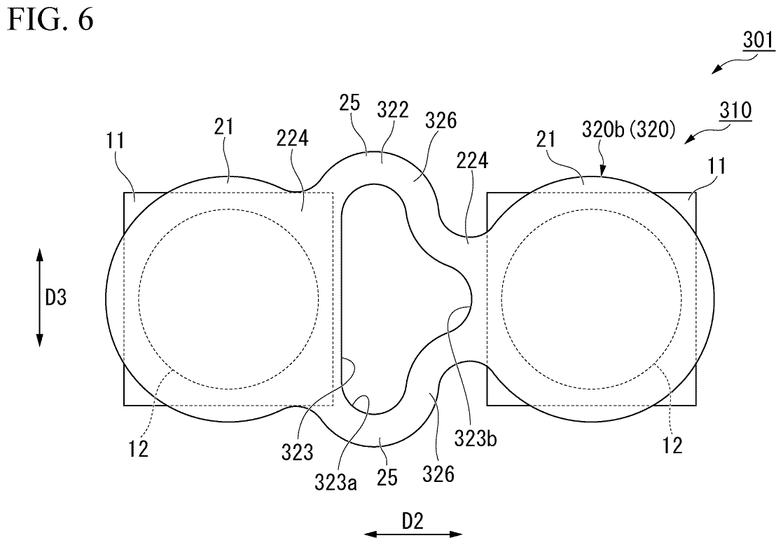

Next, a thermoelectric unit 301 that includes a thermoelectric module 310 according to a third embodiment of the present invention will be described with reference to FIG. 6. In the third embodiment, the same components as those in the embodiments described above are denoted by the same reference numerals, and detailed description thereof will be omitted.

The thermoelectric unit 301 of the present embodiment includes the temperature control target object 2, the substrate 3, the thermoelectric module 310, the heat transfer member 4, and the lead wire 5.

The thermoelectric module 310 includes the plurality of thermoelectric elements 11 and a plurality of electrodes 320. The plurality of electrodes 320 include the plurality of first electrodes 20a and a plurality of second electrodes 320b.

As shown in FIG. 6, the second electrode 320b is formed asymmetrically in the second direction D2.

The second electrode 320b has the electrode base portion 21 and a connecting portion 322.

The connecting portion 322 includes a hole portion 323, the constriction portion 224, the protruding portion 25, and a displacement absorbing portion 326.

The hole portion 323 is enlarged to protrude toward the thermoelectric element 11 on the second side in the second direction D2 out of the two thermoelectric elements 11 which are electrically connected to each other. More specifically, the hole portion 323 includes a main body hole 323a that is provided close to the thermoelectric element 11 on the first side in the second direction D2 out of the two thermoelectric elements 11 that are electrically connected to each other, and a protruding hole 323b that is continuously provided on the second side in the second direction D2 of the main body hole 323a, and the main body hole 323a extends in the third direction D3.

### Effect

The thermoelectric module 310 according to the third embodiment described above can exhibit the following effects.

In the present embodiment, the hole portion 323 is enlarged to protrude toward the thermoelectric element 11 on the second side in the second direction D2 out of the two thermoelectric elements 11 that are electrically connected to each other.

In this way, the displacement absorbing portion 326 is lengthened, and the amount of stretch and contraction in the second direction D2 of the displacement absorbing portion 326 can be secured more. Therefore, the thermoelectric module 310 can further satisfactorily relax the thermal stress by the stretch and contraction of the displacement absorbing portion 326.

### Fourth Embodiment

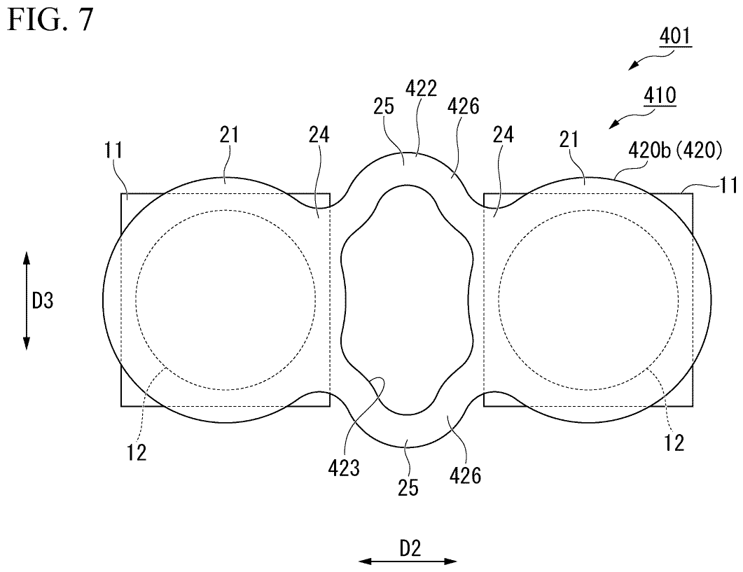

Next, a thermoelectric unit 401 that includes a thermoelectric module 410 according to a fourth embodiment of the present invention will be described with reference to FIG. 7. In the fourth embodiment, the same components as those in the embodiments described above are denoted by the same reference numerals, and a detailed description thereof will be omitted.

The thermoelectric unit 401 of the present embodiment includes the temperature control target object 2, the substrate 3, the thermoelectric module 410, the heat transfer member 4, and the lead wire 5.

The thermoelectric module 410 includes the plurality of thermoelectric elements 11 and a plurality of electrodes 420. The plurality of electrodes 420 include the plurality of first electrodes 20a and a plurality of second electrodes 420b.

As shown in FIG. 7, the second electrode 420b is formed in a shape symmetrical in the second direction D2 and the third direction D3 when viewed in the first direction D1.

The second electrode 420b has the electrode base portion 21 and a connecting portion 422.

The connecting portion 422 includes a hole portion 423, the constriction portion 24, the protruding portion 25, and a displacement absorbing portion 426.

The hole portion 423 is formed along the outer shape of the connecting portion 422.

### Effect

The thermoelectric module 410 according to the fourth embodiment described above can exhibit the following effects.

In the present embodiment, the hole portion 423 is formed along the outer shape of the connecting portion 422.

In this way, the displacement absorbing portion 426 is lengthened, and the amount of stretch and contraction in the second direction D2 of the displacement absorbing portion 426 can be secured more. Therefore, the thermoelectric module 410 can further satisfactorily relax the thermal stress by the stretch and contraction of the displacement absorbing portion 426.

Although the embodiments of the present invention have been described in detail above with reference to the drawings, the specific configurations are not limited to the embodiments, and also include design changes and the like within a range which does not depart from the gist of the present invention. For example, in the embodiments described above, a case where the second electrodes 20b, 220b, 320b, and 420b on the temperature control target object 2 side have the configurations such as the hole portions 23, 223, 323, and 423, the constriction portions 24 and 224, the protruding portions 25, and the displacement absorbing portions 26, 226, 326, and 426 has been described. However, not only the second electrodes 20b, 220b, 320b, and 420b but also the first electrode 20a on the substrate 3 side may have the same configurations as those of the second electrodes 20b, 220b, 320b, and 420b, such as the hole portions 23, 223, 323, and 423, the constriction portions 24 and 224, the protruding portions 25, and the displacement absorbing portions 26, 226, 326, and 426.

In the embodiments described above, a case where the second electrode 20b is provided on the heat absorption side and the first electrode 20a is provided on the heat radiation side has been described. However, the second electrode 20b may be provided on the heat radiation side and the first electrode 20a may be provided on the heat absorption side.

### INDUSTRIAL APPLICABILITY

According to the present invention, it is possible to avoid a reduction in the output of the thermoelectric module while relaxing the thermal stress acting on the electrode.

### REFERENCE SIGNS LIST

1 Thermoelectric unit
2 Temperature control target object
3 Substrate
4 Heat transfer member
5 Lead wire
3a Conduit line
10 Thermoelectric module
11 Thermoelectric element
12 Connection portion
20 Electrode
20a First electrode
20b Second electrode
21 Electrode base portion
22 Connecting portion
23 Hole portion
24 Constriction portion
25 Protruding portion
26 Displacement absorbing portion
201 Thermoelectric unit
210 Thermoelectric module
220 Electrode
220b Second electrode
222 Connecting portion
223 Hole portion
224 Constriction portion
226 Displacement absorbing portion
301 Thermoelectric unit
310 Thermoelectric module
320 Electrode
320b Second electrode
322 Connecting portion
323 Hole portion
323a Main body hole
323b Protruding hole
326 Displacement absorbing portion
401 Thermoelectric unit
410 Thermoelectric module
420 Electrode
420b Second electrode
422 Connecting portion
423 Hole portion
426 Displacement absorbing portion
D1 First direction
D2 Second direction
D3 Third direction
W1, W1a, W1b First width
W2 Second width
W3 Third width

1. A thermoelectric module that performs temperature control on a temperature control target object, the thermoelectric module comprising:
a plurality of thermoelectric elements that are provided between the temperature control target object and a substrate that is disposed to face the temperature control target object in a first direction; and
a plurality of electrodes that are provided on each of a substrate side and a temperature control target object side of the thermoelectric element and configured to electrically connect the thermoelectric elements adjacent to each other in a second direction intersecting the first direction,
wherein the electrode includes
two electrode base portions that are spaced apart from each other in the second direction, and each of which is connected to a corresponding thermoelectric element, and
a connecting portion connecting the two electrode base portions, and
the connecting portion is provided with
a hole portion penetrating in the first direction,
a constriction portion that is provided on each of both sides in the second direction with the hole portion interposed therebetween and that is recessed inward in a third direction intersecting the first direction and the second direction, and
a displacement absorbing portion formed along an outer shape of the connecting portion and an outer shape of the hole portion.

2. The thermoelectric module according to claim 1,
wherein the electrode has a protruding portion that is provided on an outer side in the third direction of the hole portion and protrudes in the third direction, and
the hole portion is enlarged in the third direction in accordance with the protruding portion.

3. The thermoelectric module according to claim 1,
wherein the hole portion is provided close to the thermoelectric element on a first side in the second direction out of the two thermoelectric elements that are electrically connected to each other, and
the constriction portion on a second side in the second direction is recessed further inward in the third direction than the constriction portion on the first side in the second direction.

4. The thermoelectric module according to claim 1,
wherein the hole portion is enlarged to protrude toward the thermoelectric element on the second side in the second direction out of the two thermoelectric elements that are electrically connected to each other.

5. The thermoelectric module according to claim 1,
wherein the hole portion is formed along the outer shape of the connecting portion.

6. The thermoelectric module according to claim 2,
wherein the hole portion is provided close to the thermoelectric element on a first side in the second direction out of the two thermoelectric elements that are electrically connected to each other, and
the constriction portion on a second side in the second direction is recessed further inward in the third direction than the constriction portion on the first side in the second direction.

7. The thermoelectric module according to claim 2,
wherein the hole portion is enlarged to protrude toward the thermoelectric element on the second side in the second direction out of the two thermoelectric elements that are electrically connected to each other.

8. The thermoelectric module according to claim 2,
wherein the hole portion is formed along the outer shape of the connecting portion.
